(19) United States
(12) Patent Application Publication
(10) Pub. No.: US 2026/0354083 A1
(43) Pub. Date: Nov. 5, 2026

(54) SUBSTRATE PROCESSING APPARATUS AND SUBSTRATE PROCESSING METHOD

(71) Applicant: Tokyo Electron Limited, Minato-ku, Tokyo (JP)

(72) Inventor: Akira FUJITA, Koshi-shi, Kumamoto (JP)

(21) Appl. No.: 19/486,150

(22) PCT Filed: May 13, 2024
(86) PCT No.: PCT/JP2024/017586

§ 371 Date: Nov. 20, 2025

(30) Foreign Application Priority Data
May 25, 2023 (JP) 2023-086441

(51) Int. Cl. H10P 72/00; H10P 50/68; H10P 74/20

(52) U.S. Cl. CPC H10P 72/0424; H10P 50/683; H10P 72/0604; H10P 74/203

(57) ABSTRACT

A substrate processing apparatus includes a substrate rotator configured to hold and rotate a substrate, a processing liquid supplier configured to supply a processing liquid to a peripheral portion of the substrate, and a controller configured to control the substrate rotator and the processing liquid supplier, wherein the controller controls the substrate rotator and the processing liquid supplier in an adjusted etching mode, in which a liquid film is formed in an etching region of the peripheral portion by supplying a processing liquid for liquid film formation from the processing liquid supplier to the peripheral portion while rotating the substrate and subsequently, in a state in which the liquid film is formed, a surface film of the etching region is etched by supplying a processing liquid for etching to the etching region.

### TECHNICAL FIELD

The present disclosure relates to a substrate processing apparatus and a substrate processing method.

### BACKGROUND

An apparatus for removing a natural oxide film formed in a peripheral portion of a substrate such as a semiconductor wafer by using a chemical liquid such as hydrofluoric acid is known (see Patent Document 1).

### PRIOR ART DOCUMENT

### Patent Document

Patent Document 1: Japanese Patent No. 6971699

When removing an oxide film formed in a peripheral portion of a substrate, an etching interface may become non-uniform and have a zigzagged shape. Once the etching interface on the peripheral portion of the substrate forms a zigzagged shape, it is difficult to smooth out the zigzag etching interface by subsequent machining.

The present disclosure provides a technique that is advantageous for obtaining a uniform etching interface by an etching process for a substrate.

### SUMMARY

An aspect of the present disclosure provides a substrate processing apparatus including a substrate rotator configured to hold and rotate a substrate, a processing liquid supplier configured to supply a processing liquid to a peripheral portion of the substrate, and a controller configured to control the substrate rotator and the processing liquid supplier. The controller controls the substrate rotator and the processing liquid supplier in an adjusted etching mode, in which a liquid film is formed in an etching region of the peripheral portion by supplying a processing liquid for liquid film formation from the processing liquid supplier to the peripheral portion while rotating the substrate and subsequently, in a state in which the liquid film is formed, a surface film of the etching region is etched by supplying a processing liquid for etching to the etching region.

According to the present disclosure, a uniform etching interface can be obtained by an etching process for a substate.

### BRIEF DESCRIPTION OF DRAWINGS

FIG. 1 is a diagram schematically illustrating an example of a substrate processing system.

FIG. 2 is a partial cross-sectional view schematically illustrating an example of a processing unit.

FIG. 3 is a diagram illustrating a schematic configuration of an example of a drive system that moves a first processing liquid nozzle, a second processing liquid nozzle, and a third processing liquid nozzle.

FIG. 4 is a block diagram illustrating an example of a functional configuration of a controller.

FIG. 5 is a cross-sectional view for schematically explaining an example of an etching process at a peripheral portion of a substrate.

FIG. 6 is an enlarged plan view of a peripheral portion of a substrate, and illustrates an example of a state immediately after a processing liquid nozzle discharging a processing liquid has moved from a retracted position to a processing position.

FIG. 7 is an enlarged plan view of a peripheral portion of a substrate, and illustrates an example of a liquid film of a processing liquid in a state in which at least a portion of a substrate body is exposed by etching away a surface film.

FIG. 8 is an enlarged plan view of a peripheral portion of a substrate, and illustrates another example of a liquid film of a processing liquid in a state in which at least a portion of a substrate body is exposed by etching away a surface film.

FIG. 9 is a graph illustrating an example of a processing sequence of a first standard etching mode.

FIG. 10 is a graph illustrating an example of a processing sequence of a first adjusted etching mode.

FIG. 11A is a diagram for explaining a concept of the processing sequence of the first adjusted etching mode.

FIG. 11B is a diagram for explaining the concept of the processing sequence of the first adjusted etching mode.

FIG. 11C is a diagram for explaining the concept of the processing sequence of the first adjusted etching mode.

FIG. 12 is a graph illustrating an example of a processing sequence of a second adjusted etching mode.

FIG. 13 is a graph illustrating an example of a processing sequence of a second standard etching mode.

FIG. 14 is a graph illustrating an example of a processing sequence of a third adjusted etching mode.

FIG. 15A is a diagram for explaining a concept of the processing sequence of the third adjusted etching mode.

FIG. 15B is a diagram for explaining the concept of the processing sequence of the third adjusted etching mode.

FIG. 15C is a diagram for explaining the concept of the processing sequence of the third adjusted etching mode.

FIG. 16 is a graph illustrating an example of a processing sequence of a fourth adjusted etching mode.

FIG. 17 is a graph illustrating an example of a processing sequence of a fifth adjusted etching mode.

FIG. 18 is a plan view schematically illustrating an example of a substrate to which a processing liquid (e.g., chemical liquid) for etching is being supplied from a processing liquid nozzle to a peripheral portion of the substrate.

FIG. 19A is an enlarged plan view of a region indicated by reference symbol “XIXA” in FIG. 18, and specifically illustrates an example in which the peripheral portion of the substrate to which the processing liquid for etching is supplied has hydrophilic surface properties.

FIG. 19B is an enlarged plan view of the region indicated by reference symbol “XIXA” in FIG. 18, and specifically illustrates an example in which the peripheral portion of the substrate to which the processing liquid for etching is supplied has hydrophobic surface properties.

FIG. 20 is a flowchart illustrating an example of an etching mode determination method.

### DETAILED DESCRIPTION

Exemplary embodiments of the present disclosure will be described with reference to the accompanying drawings. The shapes and sizes of individual elements illustrated in each drawings do not necessarily match the actual shapes and sizes. Likewise, the arrangement relationships and dimensional ratios among the elements also do not necessarily match the actual arrangement relationships and dimensional ratios. In addition, even among the drawings, the arrangement relationships and dimensional ratios among the elements do not necessarily match.

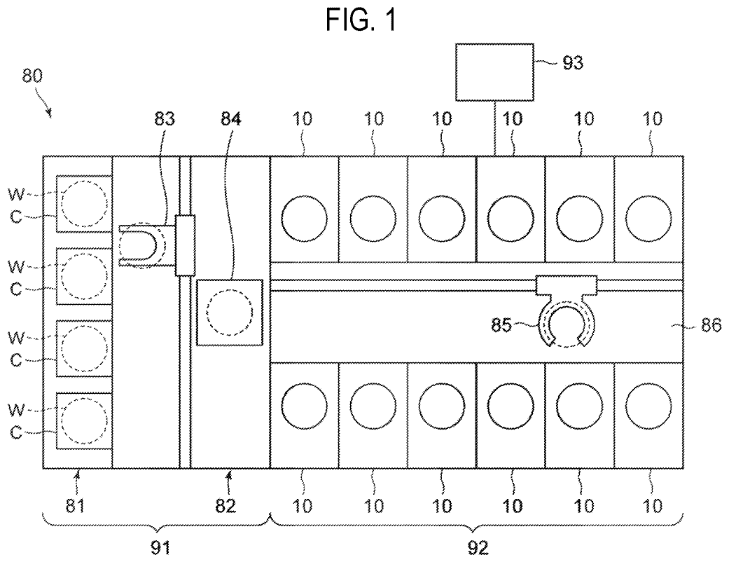

FIG. 1 is a diagram schematically illustrating an example of a substrate processing system 80.

The substrate processing system 80 shown in FIG. 1 has a load/unload station 91 and a processing station 92. The load/unload station 91 includes a stage 81 provided with a plurality of carriers C, and a transferer 82 provided with a first transfer mechanism 83, and a deliverer 84. Each carrier C accommodates therein a plurality of substrates W horizontally. The substrate W is typically configured as a semiconductor wafer, but is not limited thereto. In the processing station 92, a plurality of processing units 10 is installed on both sides of a transfer path 86, and a second transfer mechanism 85 that reciprocates along the transfer path 86 is provided.

The substrate W is taken out from the carrier C by the first transfer mechanism 83 and placed on the deliverer 84. The substrate W is then taken out from the deliverer 84 by the second transfer mechanism 85. Further, the substrate W is loaded into a corresponding processing unit 10 by the second transfer mechanism 85 and subjected to a predetermined process in the corresponding processing unit 10. Thereafter, the substrate W is taken out from the corresponding processing unit 10 by the second transfer mechanism 85 and placed on the deliverer 84. The substrate W is then returned back to the carrier C in the stage 81 by the first transfer mechanism 83. Further, the substrate W may be returned to the carrier C after being processed in two or more processing units 10.

In the above-described substrate processing system 80, two or more processing units 10 among the plurality of processing units 10 may have a same configuration or different configurations, and may perform a same process or different processes. By supplying various types of processing fluids (e.g., processing liquids such as a chemical liquid, a rinsing liquid, and a cleaning liquid) to the substrate W, each processing unit 10 can perform various processes on the substrate W.

The substrate processing system 80 includes a controller 93. The controller 93 is configured as, for example, a computer and includes an operation processor and a storage. In the storage of the controller 93, programs and data for various types of processes performed in the substrate processing system 80 are stored. The operation processor of the controller 93 appropriately reads out and executes programs stored in the storage to control individual mechanisms of the substrate processing system 80 and perform the various types of processes.

The programs and data stored in the storage of the controller 93 may have been recorded on a computer-readable storage medium and installed from the storage medium into the storage. The computer-readable storage medium may be, for example, a hard disk (HD), a flexible disk (FD), a compact disc (CD), a magneto-optical disc (MO), a memory card, or the like.

As described above, in the substrate processing system 80 illustrated in FIG. 1, the stage 81 including the plurality of carriers C functions as a substrate holding unit that holds the plurality of substrates W. In addition, each processing unit 10 functions as a substrate processing apparatus that processes each substrate W. Further, the transferer 82, the first transfer mechanism 83, the deliverer 84, the second transfer mechanism 85, and the transfer path 86 function as a substrate transfer unit that transfers each substrate W between the substrate holding unit and the substrate processing apparatus. In addition, the controller 93 functions as a processing controller that controls the substrate processing apparatus.

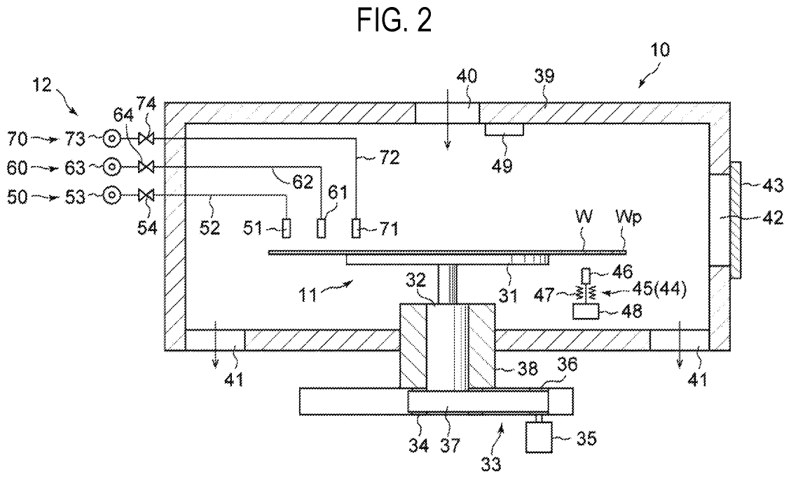

FIG. 2 is a partial cross-sectional view schematically illustrating an example of the processing unit 10.

The processing unit 10 shown in FIG. 2 is an apparatus for etching away a surface film (e.g., a natural oxide film) formed on a peripheral portion of the substrate W, and includes a substrate rotator 11 that holds and rotates the substrate W and a processing liquid supplier 12 capable of supplying a processing liquid to the substrate W (e.g., a peripheral portion Wp).

The substrate rotator 11 includes a holder 31 that horizontally holds the substrate W, a rotary shaft 32 that is installed on the holder 31 and extends downward (vertically) from the holder 31, and a rotary driver 33 that rotates the holder 31 via the rotary shaft 32.

The substrate W is held by the holder 31 while being placed on an upper surface of the holder 31, and can rotate together with the holder 31. A method of holding the substrate W by the holder 31 is not limited. For example, the holder 31 may hold the substrate W by vacuum suction.

The rotary shaft 32 is rotatably supported by a chamber 39 via a bearing 38. The rotary driver 33 includes a pulley 34 attached to a lower end of the rotary shaft 32, a motor 35, a pulley 36 attached to a rotary shaft of the motor 35, and a drive belt 37 wound around the pulleys 34 and 36. A rotational driving force of the motor 35 is transmitted to the rotary shaft 32 via the pulley 36, the drive belt 37, and the pulley 34, and causes the rotary shaft 32 to rotate. Further, the holder 31 and the substrate W rotate integrally with the rotary shaft 32.

The holder 31 is disposed inside the chamber 39, and the substrate W held by the holder 31 is located inside the chamber 39. A ceiling of the chamber 39 has an upper opening 40. A gas (e.g., an inert gas such as nitrogen) is supplied from a not shown fan filter unit (FFU) into the chamber 39 via the upper opening 40 and forms a downflow inside the chamber 39. A bottom of the chamber 39 has a lower opening 41, and a gas inside the chamber 39 is discharged to the outside via the lower opening 41. A side portion of the chamber 39 has a side opening 42, and a shutter 43 for opening and closing the side opening 42 is installed on the side portion of the chamber 39. The substrate W is loaded from the outside into the chamber 39 and unloaded from the inside of the chamber 39 to the outside via the side opening 42.

The processing liquid supplier 12 may have any configuration as long as the processing liquid supplier 12 can supply a processing liquid for liquid film formation and a processing liquid for etching to the peripheral portion Wp of the substrate W, as will be described later. The processing liquid supplier 12 illustrated in FIG. 2 includes a first processing liquid supplier 50, a second processing liquid supplier 60, and a third processing liquid supplier 70.

The first processing liquid supplier 50 includes a first processing liquid nozzle 51 disposed inside the chamber 39, a first processing liquid source 53 connected to the first processing liquid nozzle 51 via a first processing liquid supply pipe 52, and a first processing liquid valve 54 provided in the first processing liquid supply pipe 52. The first processing liquid nozzle 51 discharges a first processing liquid supplied from the first processing liquid source 53 via the first processing liquid supply pipe 52. A flow rate of the first processing liquid flowing through the first processing liquid supply pipe 52 is regulated by the first processing liquid valve 54. That is, the first processing liquid valve 54 regulates supply and stop of the first processing liquid to the first processing liquid nozzle 51 and a supply amount of the first processing liquid, under control of the controller 93 (see FIG. 1).

Similarly, in the second processing liquid supplier 60, a second processing liquid nozzle 61 disposed inside the chamber 39 discharges a second processing liquid supplied from a second processing liquid source 63 via a second processing liquid supply pipe 62. The second processing liquid valve 64 regulates supply and stop of the second processing liquid to the second processing liquid nozzle 61 and a supply amount of the second processing liquid, under control of the controller 93. Further, in the third processing liquid supplier 70, a third processing liquid nozzle 71 disposed inside the chamber 39 discharges a third processing liquid supplied from a third processing liquid source 73 via a third processing liquid supply pipe 72. The third processing liquid valve 74 regulates supply and stop of the third processing liquid to the third processing liquid nozzle 71 and a supply amount of the third processing liquid, under control of the controller 93.

Specific compositions of the first processing liquid, the second processing liquid, and the third processing liquid, which are discharged from the first processing liquid nozzle 51, the second processing liquid nozzle 61, and the third processing liquid nozzle 71, respectively, as described above, are not limited. As an example, the first processing liquid discharged from the first processing liquid nozzle 51 may be deionized water (DIW). The second processing liquid discharged from the second processing liquid nozzle 61 may be hydrofluoric acid (e.g., dilute hydrofluoric acid (DHF)). The third processing liquid discharged from the third processing liquid nozzle 71 may be SC1 (a liquid mixture of ammonia and hydrogen peroxide).

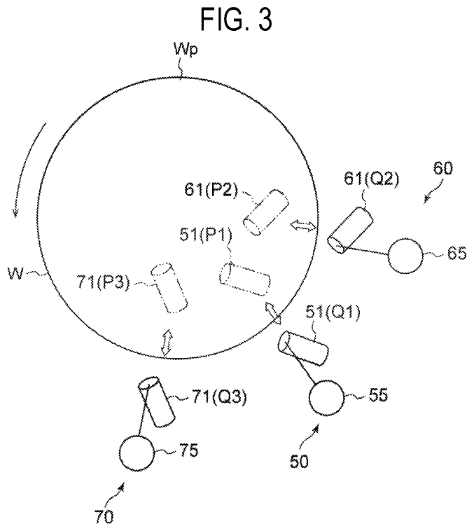

FIG. 3 is a diagram illustrating a schematic configuration of an example of a drive system that moves the first processing liquid nozzle 51, the second processing liquid nozzle 61, and the third processing liquid nozzle 71.

The first processing liquid nozzle 51, the second processing liquid nozzle 61, and the third processing liquid nozzle 71 of the present embodiment may have any configuration appropriate for discharging the first to third processing liquids toward the peripheral portion Wp of the substrate W. In the example shown in FIG. 3, the first processing liquid nozzle 51, the second processing liquid nozzle 61, and the third processing liquid nozzle 71 are disposed so that the first to third processing liquids are supplied at a predetermined angle with respect to the peripheral portion Wp (specifically an upper surface of the substrate W). Discharge angles of the first to third processing liquids from the first processing liquid nozzle 51, the second processing liquid nozzle 61, and the third processing liquid nozzle 71 are not limited. For example, each of the processing liquid nozzles 51, 61, and 71 may discharge a corresponding processing liquid toward a downstream side of a rotational direction of the substrate W obliquely with respect to a vertical direction. Alternatively, each of the processing liquid nozzles 51, 61, and 71 may discharge a corresponding processing liquid toward a downstream side of the rotational direction of the substrate W obliquely with respect to a radial direction (i.e., radially outward direction) of the substrate W in a plan view.

The first processing liquid nozzle 51, the second processing liquid nozzle 61, and the third processing liquid nozzle 71 may be disposed at processing positions P1, P2, and P3 for discharging the processing liquids toward the peripheral portion Wp of the substrate W and at retracted positions Q1, Q2, and Q3, which are different from the processing positions in the radial direction of the substrate W. The processing positions P1, P2, and P3 are set such that processing liquids discharged from the respective processing liquid nozzles 51, 61, and 71 disposed at the processing positions P1, P2, and P3 are supplied to a desired region (an etching region to be described later) in the peripheral portion Wp of the substrate W. On the other hand, the retracted positions Q1, Q2, and Q3 are set such that even when processing liquids are discharged from the respective processing liquid nozzles 51, 61, and 71 disposed at the retracted positions Q1, Q2, and Q3, the processing liquids do not reach the substrate W.

In the example shown in FIG. 3, the first processing liquid nozzle 51 is moved between the processing position P1 and the retracted position Q1 by a first nozzle driver 55, which is driven under control of the controller 93. Similarly, the second processing liquid nozzle 61 and the third processing liquid nozzle 71 are moved between the processing positions P2 and P3 and the retracted positions Q2 and Q3 by a second nozzle driver 65 and a third nozzle driver 75, which are driven under control of the controller 93.

The processing unit 10 shown in FIG. 2 further includes a heating mechanism 44 that heats the substrate W held by the holder 31, and an imaging device 49 that images the upper surface (processing surface) of the substrate W held by the holder 31.

The heating mechanism 44 in this example includes a heat fluid supplier 45 that discharges an inert gas (heat fluid) such as nitrogen gas heated by a heater 47, and the substrate W held by the holder 31 is heated by using the inert gas discharged from the heat fluid supplier 45. In the heat fluid supplier 45 illustrated in FIG. 2, the inert gas sent from a heat fluid source 48 is discharged from a heat fluid ejector 46 toward a back surface of the substrate W under control of the controller 93 (see FIG. 1). The inert gas is heated by the heater 47 while traveling from the heat fluid source 48 to the heat fluid ejector 46 via a transfer line. In addition, the heating mechanism 44 is not limited to a configuration that heats the substrate W by the heat fluid, and may heat the substrate W by using, for example, a heater that uses another heating device, such as a lamp or a laser, disposed above or below the substrate W.

The imaging device 49 performs imaging under control of the controller 93 (see FIG. 1) to acquire imaging data (captured image data) of the upper surface (processing surface) of the substrate W, and sends the imaging data to the controller 93. An installation position of the imaging device 49 is not limited to the example shown in FIG. 2, and the imaging device 49 may be installed at any position and with any posture as long as the imaging device 49 can acquire imaging data by imaging a desired location on the upper surface (especially the peripheral portion Wp) of the substrate W.

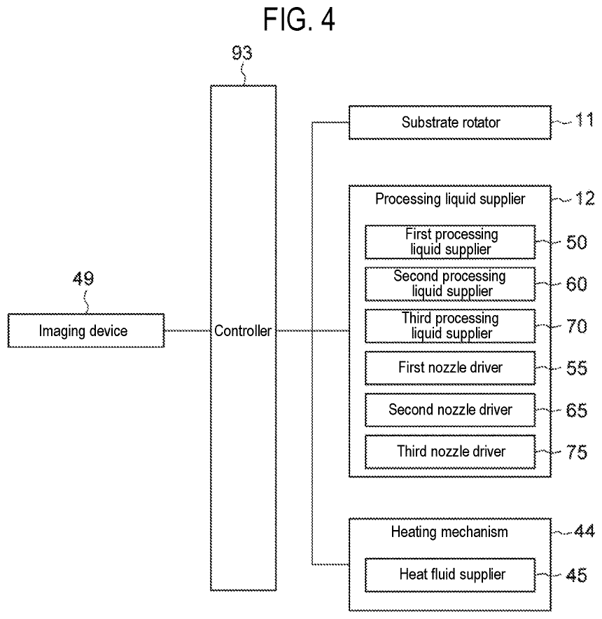

FIG. 4 is a block diagram illustrating an example of a functional configuration of the controller 93.

The controller 93 controls individual components of the processing unit 10. The components of the processing unit 10 controlled by the controller 93 are not limited, and control targets and contents of control are determined according to a content of processing.

The controller 93 of the present embodiment controls, for example, the substrate rotator 11, the processing liquid supplier 12, the heating mechanism 44, and the imaging device 49, as shown in FIG. 4, in order to remove a natural oxide film formed in the peripheral portion Wp of the substrate W. Specific contents of control by the controller 93 will be described later.

### [Etching Method (Substrate Processing Method)]

As described above, when the surface film in the peripheral portion Wp of the substrate W is etched away, an etching interface may become non-uniform and have a zigzag shape.

As a result of repetitive researches and trials-and-errors regarding such a non-uniform etching interface, the present inventor found that the etching interface tends to be made more non-uniform as an etching rate increases.

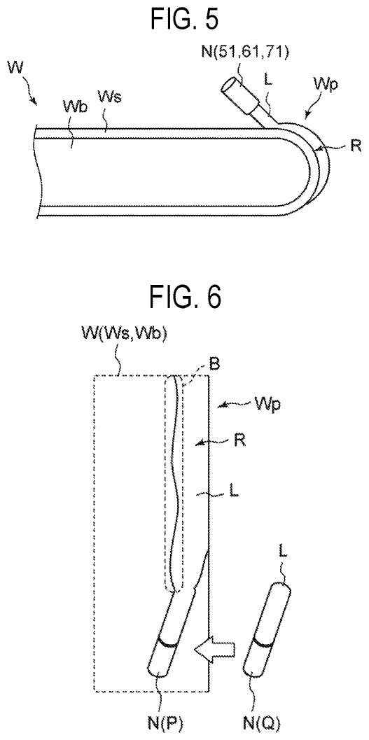

FIG. 5 is a cross-sectional view for schematically explaining an example of an etching process at the peripheral portion Wp of the substrate W.

Generally, a surface film Ws covering a surface of a substrate body Wb such as silicon (Si) is etched away by using a processing liquid L discharged from a processing liquid nozzle N (corresponding to the processing liquid nozzles 51, 61, and 71 shown in FIGS. 2 and 3). In the example shown in FIG. 5, the processing liquid L is discharged from the processing liquid nozzle N especially toward the peripheral portion Wp of the substrate W, and the surface film Ws is etched away from the peripheral portion Wp.

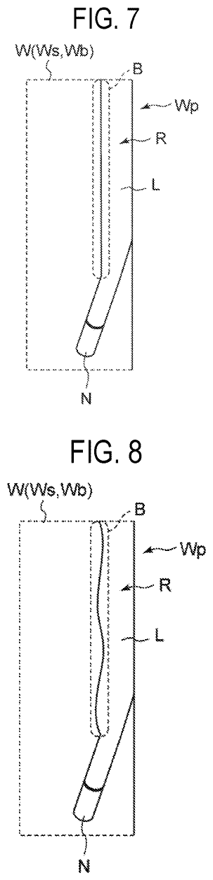

FIG. 6 is an enlarged plan view of the peripheral portion Wp of the substrate W, and illustrates an example of a state immediately after the processing liquid nozzle N discharging the processing liquid L has moved from a retracted position Q (corresponding to the retracted positions Q1 to Q3 shown in FIG. 3) to a processing position P (corresponding to the processing positions P1 to P3 shown in FIG. 3). FIG. 7 is an enlarged plan view of the peripheral portion Wp of the substrate W, and illustrates an example of a liquid film of the processing liquid L in a state in which at least a portion of the substrate body Wb is exposed by etching away the surface film Ws. FIG. 8 is an enlarged plan view of the peripheral portion Wp of the substrate W, and illustrates another example of the liquid film of the processing liquid L in a state in which at least a portion of the substrate body Wb is exposed by etching away the surface film Ws.

The processing liquid L (especially a processing liquid for etching), which is discharged from the processing liquid nozzle N located at the processing position P, lands on the peripheral portion Wp of the rotating substrate W, spreads over an etching region R in the peripheral portion Wp, and forms a liquid film. This liquid film of the processing liquid L gradually etches away the surface film Ws in the etching region R and gradually exposes the substrate body Wb.

Therefore, for example, when a hydrophobic substrate body Wb is covered with a hydrophilic surface film Ws, the etching region R changes from an entirely hydrophilic state to a mixed state of hydrophilicity and hydrophobicity and finally reaches an entirely hydrophobic state, as etching progresses. On the other hand, when a hydrophilic substrate body Wb is covered with a hydrophobic surface film Ws, the etching region R changes from an entirely hydrophobic state to a mixed state of hydrophobicity and hydrophilicity and finally reaches an entirely hydrophilic state, as etching progresses.

As described above, when the substrate body Wb and the surface film Ws have different “affinities to water (hydrophilicity/hydrophobicity),” a state in which both a hydrophobic region and a hydrophilic region are present at the peripheral portion Wp of the substrate W appears in the process of etching away the surface film Ws.

Further, immediately after the processing liquid nozzle N is moved from the retracted position Q to the processing position P, a state of the liquid film of the processing liquid L in the etching region R may be unstable, and a contour of the liquid film (especially an interface (gas-liquid interface B) on a side of a center of the substrate) may have an irregular and zigzagged shape as shown in FIG. 6. Thereafter, the shape of the liquid film of the processing liquid L, which is discharged from the processing liquid nozzle N, in the etching region R is gradually stabilized as the time lapses, and ideally, the contour of the liquid film (especially the interface B on the side of the center of the substrate) has a regular shape (see FIG. 7).

However, in reality, even as the time lapses, the shape of the liquid film of the processing liquid L in the etching region R may not be stabilized, and the contour of the liquid film (especially the interface B on the side of the center of the substrate) may continue to maintain the irregular and zigzagged shape (see FIG. 8). In such a case, the shape of the etching interface may eventually become non-uniform and have a zigzagged shape.

As a result of repetitive researches and trials-and-errors, the present inventor also found that when both a hydrophilic surface and a hydrophobic surface are exposed from the etching region R in a state in which the shape of the liquid film of the processing liquid L in the etching region R is not sufficiently stabilized, the etching interface easily becomes non-uniform and zigzag. In other words, it was found that when both a hydrophilic surface and a hydrophobic surface are exposed from the etching region R in a state in which the contour of the liquid film of the processing liquid L in the etching region R (especially the interface B on the side of the center of the substrate) is irregular, the contour of the liquid film tends to continue to maintain an irregular shape.

More specifically, when the substrate body Wb is exposed by etching away the surface film Ws before the contour of the liquid film (interface B) of the processing liquid L in the etching region R reaches a state of having a desired regular shape, the shape of the etching interface tends to become non-uniform and have a zigzagged shape. It is considered that the reason is because both a location (hydrophilic surface) where a liquid easily exists and a location (hydrophobic surface) where the liquid hardly exists are generated in the etching region R while a liquid film remains unstable, which hinders stabilization of the shape of the liquid film and the unstable state of the shape of the liquid film is maintained during the etching process.

Based on the findings described above, the present inventor has newly found that, performing the etching process as described below is advantageous in effectively avoiding the non-uniform shape of the etching interface and in achieving an etching interface having a desired regular shape.

That is, in a state in which a processing liquid for liquid film formation is supplied to the peripheral portion Wp of the substrate W and a stable liquid film is formed in the etching region R, by supplying a processing liquid for etching to the etching region R to remove the surface film Ws, the shape of the etching interface is effectively suppressed from being made non-uniform.

More specifically, by forming a liquid film of the processing liquid L having a well-defined shape in the etching region R before the substrate body Wb is exposed from the etching region R, the etching interface of the etching region R after the etching process can have a more uniform shape.

In addition, the processing liquid for liquid film formation mentioned in this specification is a processing liquid having a lower etching rate for etching the surface film Ws than that of the processing liquid for etching, and is, for example, a processing liquid having a lower concentration of an etching component for etching the surface film Ws than that of the processing liquid for etching.

Therefore, the processing liquid for liquid film formation may be, for example, a processing liquid that does not etch the surface film Ws, and the etching rate of the surface film Ws by the processing liquid for liquid film formation may be substantially “zero (0).” As another example, a processing liquid L1 for liquid film formation may be a processing liquid that etches the surface film Ws, and may be a liquid mixture of a processing liquid that etches the surface film Ws and a processing liquid that does not etch the surface film Ws. In addition, the processing liquid for etching may be a processing liquid having a more appropriate temperature for etching the surface film Ws (a temperature that achieves a higher etching rate) on the substrate W than that of the processing liquid for liquid film formation, and may be, for example, a processing liquid having a higher temperature on the substrate W than that of the processing liquid for liquid film formation.

Hereinafter, a more specific etching method will be described.

In each etching mode described below, as an example, DIW supplied to the peripheral portion Wp of the substrate W by the first processing liquid supplier 50 (see FIGS. 2 and 3) is used as the first processing liquid that does not etch the surface film Ws (e.g., an oxide film).

Further, a chemical liquid Lc (e.g., hydrofluoric acid) supplied to the peripheral portion Wp of the substrate W by the second processing liquid supplier 60 (see FIGS. 2 and 3) is used as the second processing liquid that etches the surface film Ws.

### [First Standard Etching Mode]

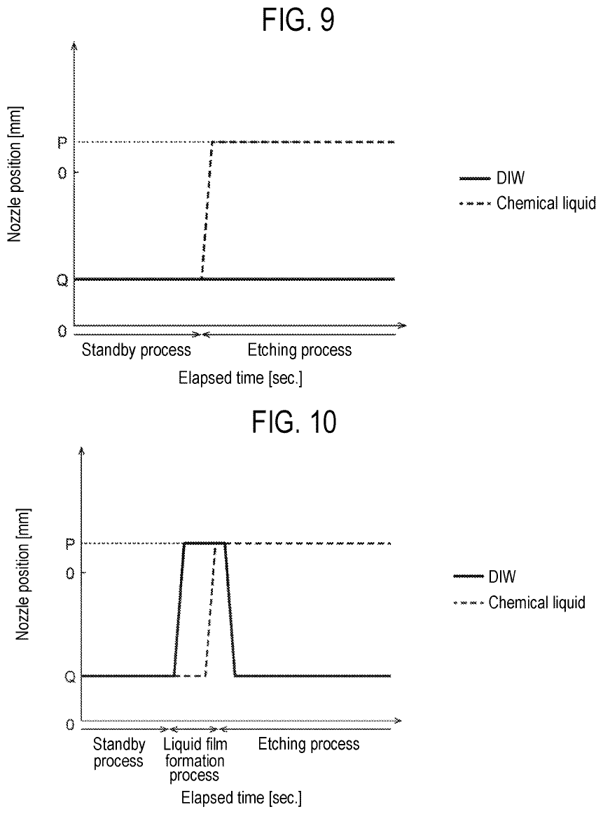

FIG. 9 is a graph illustrating an example of a processing sequence in a first standard etching mode.

A horizontal axis in FIG. 9 represents an elapsed time (seconds), and an end position on a left-hand side of the horizontal axis represents an origin “0.” A vertical axis in FIG. 9 represents a nozzle position. The above-described processing position P exists on a positive side (upper side in FIG. 9) of the vertical axis relative to the origin “0,” and the above-described retracted position Q exists on a negative side (lower side in FIG. 9) of the vertical axis relative to the origin “0.”

FIG. 9 illustrates a case in which “DIW” an example of a liquid that does not substantially contribute to the etching process for the surface film Ws of the substrate W and a “chemical liquid” as a liquid that substantially contributes to the etching process for the surface film Ws of the substrate W can be supplied to the peripheral portion Wp of the substrate W. As an example, a case in which the “DIW” shown in FIG. 9 is discharged from the “first processing liquid nozzle 51” shown in FIGS. 2 and 3, and the “chemical liquid” shown in FIG. 9 is discharged from the “second processing liquid nozzle 61” shown in FIGS. 2 and 3 will be described.

However, the graph regarding the “DIW” and the “chemical liquid” shown in FIG. 9 is only an example of a standard sequence of the etching process, and the first standard etching mode based on another sequence may be performed. Instead of the “DIW” shown in FIG. 9, another processing liquid having a lower contribution to the etching process for the surface film Ws than the “chemical liquid” may be used. For example, in a case where the surface film Ws is made of a material (e.g., aluminum oxide (AlOₓ) or germanium oxide (GeOₓ)) that can be etched by DIW, a processing liquid that does not etch the material may be used instead of the DIW in FIG. 9, and DIW may be used instead of the chemical liquid in FIG. 9. As such a processing liquid that does not etch the surface film Ws, for example, isopropyl alcohol (IPA) or acetone may be used.

In addition, the processing liquid nozzle N from which the “DIW” and the “chemical liquid” are discharged is not limited and, for example, the “chemical liquid” may be discharged from the “third processing liquid nozzle 71 (third processing liquid supplier 70)” shown in FIGS. 2 and 3.

In the first standard etching mode illustrated in FIG. 9, in a standby process in which processing liquids (the DIW and the chemical liquid) are not supplied to the substrate W, nozzles (in this example, the first processing liquid nozzle 51 and the second processing liquid nozzle 61) for discharging the chemical liquid and the DIW are positioned at the retracted position Q. On the other hand, in an etching process in the first standard etching mode in which the etching region R (especially the surface film Ws) of the peripheral portion Wp of the substrate W is etched, the second processing liquid nozzle 61 is moved from the retracted position Q to the processing position P. Further, the chemical liquid discharged from the second processing liquid nozzle 61 positioned at the processing position P is supplied to the etching region R to etch the surface film Ws in the etching region R. In the etching process illustrated in FIG. 9, the first processing liquid nozzle 51 is continuously positioned at the retracted position Q, and the DIW is not supplied from the first processing liquid nozzle 51 to the substrate W.

In the first standard etching mode of FIG. 9, according to processing conditions, the etching process may proceed while the shape of the liquid film of the processing liquid L in the etching region R is stabilized insufficiently as described above. As a result, the shape of the etching interface may be made non-uniform and zigzag (see FIG. 8).

### [First Adjusted Etching Mode]

Next, a first adjusted etching mode, which is effective in promoting uniformity in the shape of the etching interface, will be described.

FIG. 10 is a graph illustrating an example of a processing sequence of the first adjusted etching mode. Similar to the horizontal and vertical axes in FIG. 9 described above, a horizontal axis and a vertical axis in FIG. 10 represent an elapsed time (seconds) and a nozzle position, respectively.

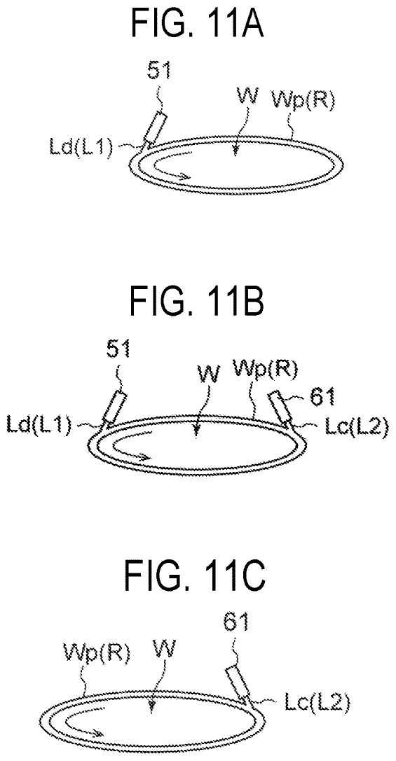

FIGS. 11A to 11C are diagrams for explaining a concept of a processing sequence of the first adjusted etching mode.

In the first adjusted etching mode, the surface film Ws in the etching region R is etched by starting a supply of a processing liquid L2 for etching to the etching region R of the peripheral portion Wp of the substrate W in a state in which a liquid film of the processing liquid L1 for liquid film formation is stably formed in a desired shape.

That is, the controller 93 (see FIG. 1) controls the substrate rotator 11 and the processing liquid supplier 12 (see FIG. 2) to sequentially perform a liquid film formation process and an etching process while rotating the substrate W supported by the holder 31.

In the liquid film formation process, DIW (see reference symbol “Ld” in FIGS. 11A to 11C; hereinafter also referred to as “DIWLd”) is supplied from the first processing liquid nozzle 51 of the processing liquid supplier 12 to the peripheral portion Wp of the substrate W. As a result, in the liquid film formation process, a liquid film of the DIWLd (i.e., the processing liquid L1 for liquid film formation) is formed in the etching region R of the peripheral portion Wp (see FIG. 11A).

In the example shown in FIG. 10, after the standby process in which the first processing liquid nozzle 51 and the second processing liquid nozzle 61 are positioned at the retracted position Q, the first processing liquid nozzle 51 discharging the DIWLd is moved to the processing position P, and the DIWLd acting as the processing liquid L1 for liquid film formation is supplied to the peripheral portion Wp. As described above, the liquid film formation process is performed by supplying the DIWLd from the first processing liquid supplier 50 to the etching region R while supplying the chemical liquid Lc from the second processing liquid supplier 60 to the etching region R is stopped.

In the subsequent etching process, the chemical liquid Lc is supplied from the second processing liquid nozzle 61 of the processing liquid supplier 12 to the peripheral portion Wp of the substrate W (see FIG. 11B), and a liquid film of the chemical liquid Lc (i.e., the processing liquid L2 for etching) is formed in the etching region R of the peripheral portion Wp (see FIG. 11C).

Specifically, in a state in which the first processing liquid nozzle 51 discharging the DIWLd is positioned at the processing position P, the second processing liquid nozzle 61 is moved from the retracted position Q to the processing position P. Thereafter, in a state in which the second processing liquid nozzle 61 discharging the chemical liquid Lc is positioned at the processing position P, the first processing liquid nozzle 51 is moved from the processing position P to the retracted position Q.

Therefore, while the DIWLd is continuously supplied from the first processing liquid supplier 50 to the etching region R, supplying the chemical liquid Lc from the second processing liquid supplier 60 to the etching region R is started. As described above, in a state in which the liquid film of the DIWLd (the processing liquid L1 for liquid film formation) is formed in the etching region R of the peripheral portion Wp of the substrate W, a supply of the chemical liquid Lc (the processing liquid L2 for etching) is started.

Thereafter, the supply of DIWLd from the first processing liquid supplier 50 to the etching region R is stopped, while the supply of the chemical liquid Lc from the second processing liquid supplier 60 to the etching region R continues. Therefore, in a state in which the chemical liquid Lc (the processing liquid L2 for etching) is supplied to the etching region R of the peripheral portion Wp of the substrate W, supplying the DIWLd (the processing liquid L1 for liquid film formation) is stopped.

Further, after the surface film Ws in the etching region R of the substrate W is removed, the second processing liquid nozzle 61 is moved from the processing position P to the retracted position Q, the supply of the chemical liquid Lc to the peripheral portion Wp is stopped, and the etching process ends.

By starting and performing the etching process according to a series of sequences as described above, a composition of the liquid film can be altered from the DIWLd (the processing liquid L1 for liquid film formation) to the chemical liquid Lc (the processing liquid L2 for etching), while suppressing disturbance in the shape of the liquid film in the etching region R.

Further, the surface film Ws in the etching region R is etched by the liquid film of the chemical liquid Lc formed in the manner described above. In this adjusted etching mode, the processing liquid supplied to the etching region R can be changed from the DIWLd (the processing liquid L1 for liquid film formation) to the chemical liquid Lc (the processing liquid L2 for etching) in a state in which the surface film Ws is maintained and the substrate body Wb is not exposed from the etching region R. Therefore, the processing liquid supplied to the etching region R can be changed while an affinity to water (hydrophilicity/hydrophobicity) of the etching region R remains uniform overall. As a result, the chemical liquid Lc can be supplied to the etching region R without excessively disturbing the state of the liquid film that has been formed during the liquid film formation process.

According to this adjusted etching mode as described above, the etching process can be started and performed while the liquid film of the processing liquid L1 for liquid film formation in the etching region R (especially the interface B on the side of the center of the substrate) stably maintains a regular shape. Thus, it is possible to effectively prevents the shape of the etching interface from becoming non-uniform and having a zigzagged shape, and to achieve an etching interface with a regular contour that is closer to an ideal state.

### [Second Adjusted Etching Mode]

Next, a second adjusted etching mode, which is effective in promoting uniformity in the shape of the etching interface, will be described.

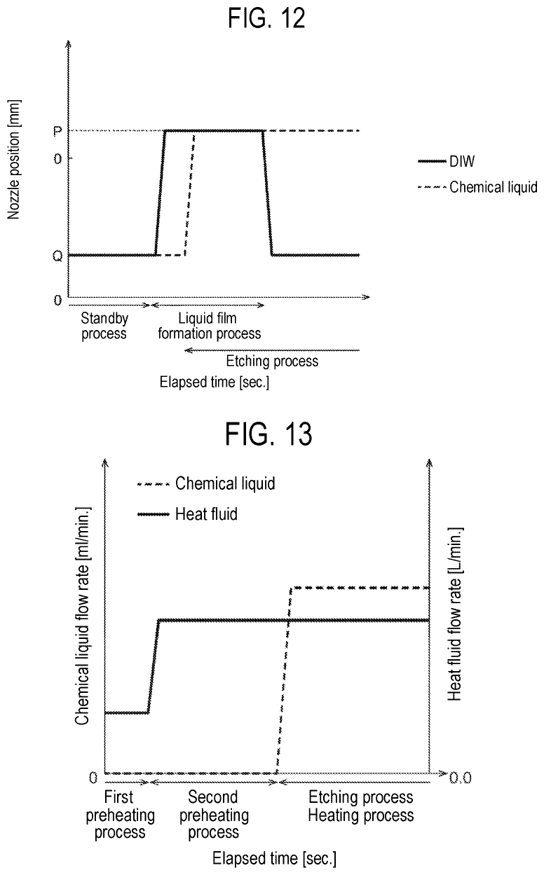

FIG. 12 is a graph illustrating an example of a processing sequence of the second adjusted etching mode. Similar to the horizontal and vertical axes of FIG. 10 described above, a horizontal axis and a vertical axis of FIG. 12 represent an elapsed time (seconds) and a nozzle position, respectively.

In the second adjusted etching mode, DIWLd and the chemical liquid Lc are supplied to the peripheral portion Wp of the substrate W to form the liquid film of the processing liquid L1 for liquid film formation in the etching region R of the peripheral portion Wp. That is, in this adjusted etching mode, the processing liquid L1 for liquid film formation includes DIWLd and the chemical liquid Lc. Further, by stopping the supply of the DIWLd while continuously supplying the chemical liquid Lc to the peripheral portion Wp, the processing liquid L2 for etching is supplied to the etching region R.

In the second adjusted etching mode, the controller 93 (see FIG. 1) controls the substrate rotator 11 and the processing liquid supplier 12 (see FIG. 2) to perform a liquid film formation process and an etching process as described below while rotating the substrate W supported by the holder 31.

That is, the liquid film formation process is performed by supplying the DIWLd from the first processing liquid nozzle 51 of the processing liquid supplier 12 to the peripheral portion Wp of the substrate W and supplying the chemical liquid Lc from the second processing liquid nozzle 61 to the peripheral portion Wp.

In the example illustrated in FIG. 12, the supply of the DIWLd to the peripheral portion Wp is started first, and then the supply of the chemical liquid Lc to the peripheral portion Wp is started. That is, the DIWLd is supplied from the first processing liquid supplier 50 to the etching region R, while the supply of the chemical liquid Lc from the second processing liquid supplier 60 to the etching region R is stopped. Thereafter, while continuously supplying the DIWLd from the first processing liquid supplier 50 to the etching region R, the chemical liquid Lc is supplied from the second processing liquid supplier 60 to the etching region R, thereby forming the liquid film of the processing liquid L1 for liquid film formation in the etching region R.

In the liquid film formation process described above, a concentration of the chemical liquid Lc can be diluted by the DIWLd. Thus, it is possible to effectively prevent the surface film Ws in the etching region R from being etched by the chemical liquid Lc supplied to the peripheral portion Wp, and to prevent the substrate body Wb from being exposed.

Further, a start timing of supplying the DIWLd and a start timing of supplying the chemical liquid Lc in the liquid film formation process are not limited to the example illustrated in FIG. 12. That is, in the liquid film formation process, as long as the liquid film of the processing liquid L1 for liquid film formation can be stably formed in the etching region R before the substrate body Wb is exposed, the DIWLd and the chemical liquid Lc may be supplied to the substrate W at any timings. Accordingly, the start timing of supplying the chemical liquid Lc to the peripheral portion Wp may be immediately after the start timing of supplying the DIWLd to the peripheral portion Wp, or may be the same as the start timing of supplying the DIWLd to the peripheral portion Wp.

Thereafter, in a state in which the liquid film of the processing liquid L1 for liquid film formation is formed in a stable shape in the etching region R as described above, the liquid film formation process ends whereas the etching process continues. That is, the supply of the DIWLd from the first processing liquid supplier 50 to the etching region R is stopped, and the supply of the chemical liquid Lc from the second processing liquid supplier 60 to the etching region R continues. More specifically, the first processing liquid nozzle 51 discharging the DIWLd is moved from the processing position P to the retracted position Q, and the second processing liquid nozzle 61 discharging the chemical liquid Lc is continuously positioned at the processing position P.

After the surface film Ws in the etching region R of the substrate W is removed, the second processing liquid nozzle 61 is moved from the processing position P to the retracted position Q, the supply of the chemical liquid Lc to the peripheral portion Wp is stopped, and the etching process ends.

By performing a series of processing sequences described above, a composition of the liquid film can be altered from the processing liquid L1 for liquid film formation (a mixture of the DIWLd and the chemical liquid Lc) to the processing liquid L2 for etching (the chemical liquid Lc) while suppressing disturbance in the shape of the liquid film in the etching region R.

As described above, this adjusted etching mode prevents the substrate body Wb from being exposed before the liquid film of a stable shape is formed in the etching region R, by controlling a concentration of the etching component that etches the surface film Ws of the substrate W. Accordingly, in this adjusted etching mode as well, the etching process can be performed while the shape of the liquid film of the processing liquid L1 for liquid film formation in the etching region R (especially a contour of the interface B on the side of the center of the substrate) stably maintains a regular shape. In particular, in this adjusted etching mode, the etching process of etching away the surface film Ws is performed not only after the liquid film formation process is performed but also while the liquid film formation process is being performed. Therefore, according to this adjusted etching mode, compared to the first adjusted etching mode described above, a total time period from a start of the liquid film formation process to an end of the etching process can be shortened.

### [Second Standard Etching Mode]

FIG. 13 is a graph illustrating an example of a processing sequence of a second standard etching mode.

A horizontal axis in FIG. 13 represents an elapsed time (seconds). A vertical axis on the left-hand side in FIG. 13 represents a flow rate (ml/minute) of a chemical liquid, which is a flow rate of the chemical liquid Lc discharged from the processing liquid nozzle N (the second processing liquid nozzle 61 in this example). A vertical axis on the right-hand side in FIG. 13 represents a flow rate of an “inert gas discharged from the heat fluid ejector 46 of the heat fluid supplier 45 (see FIG. 2)” (a flow rate (L/minute) of the heat fluid), which is a heat fluid for use in heating the substrate W supported by the substrate rotator 11.

In the second standard etching mode illustrated in FIG. 13, an etching process is started in a state in which a temperature of the substrate W (especially the peripheral portion Wp) is adjusted to a temperature appropriate for etching the surface film Ws of the substrate W.

That is, prior to the etching process in which the chemical liquid Lc is supplied to the substrate W, a preheating process in which the inert gas (heat fluid) is supplied to the substrate W to increase the temperature of the substrate W (especially the peripheral portion Wp) is performed.

In the example illustrated in FIG. 13, after a first preheating process of ejecting the inert gas from the heat fluid supplier 45 to the substrate W at a relatively low flow rate, a second preheating process of ejecting the inert gas from the heat fluid supplier 45 to the substrate W at a relatively high flow rate is performed. The second preheating process causes a greater temperature increase of the substrate W per unit time than the first preheating process. Further, the first preheating process may gradually increase the temperature of the substrate W over time, but the temperature of the substrate W does not necessarily have to be increased gradually. For example, the temperature of the substrate W may be substantially constant during at least a portion of the first preheating process (e.g., the entire period).

In a state in which the substrate W is sufficiently heated by the preheating processes (especially the second preheating process), the etching process is performed on the surface film Ws by supplying the chemical liquid Lc to the substrate W. By starting the etching process in a state in which an etching rate of the surface film Ws by the chemical liquid Lc is increased by the preheating processes as described above, an efficient etching process can be achieved. In the example shown in FIG. 13, the second processing liquid nozzle 61 is positioned at the retracted position Q during the “first preheating process” and the “second preheating process,” and is positioned at the processing position P2 during the “etching process.”

In the example illustrated in FIG. 13, even after the etching process is started, the inert gas is ejected to the substrate W at the same flow rate as in the second preheating process, and a heating process for heating the substrate W is performed simultaneously with the etching process.

According to the above-described standard etching mode, since the efficient etching process for the surface film Ws of the substrate W proceeds immediately after the supply of the chemical liquid Lc to the substrate W is started, a time period required for exposing the substrate body Wb is relatively short. Therefore, in this standard etching mode as well, as in the first standard etching mode described above (see FIG. 9), the substrate body Wb may be exposed in a state in which the shape of the liquid film of the chemical liquid Lc in the etching region R is not sufficiently stable, and the shape of the etching interface may become non-uniform and have a zigzagged shape.

A third adjusted etching mode described below is effective in suppressing non-uniformity in the shape of the etching interface caused by the second standard etching mode.

### [Third Adjusted Etching Mode]

Next, a third adjusted etching mode, which is effective in promoting uniformity in the shape of the etching interface, will be described.

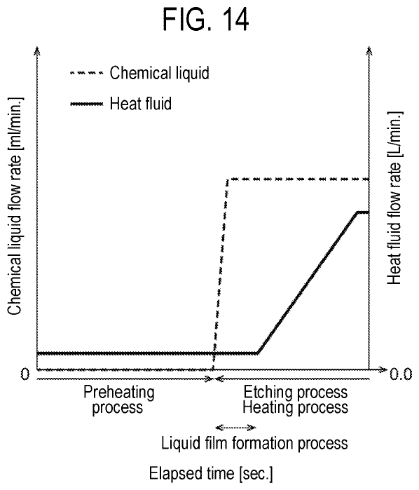

FIG. 14 is a graph illustrating an example of a processing sequence of the third adjusted etching mode. Similar to the horizontal axis, the vertical axis on the left-hand side, and the vertical axis on the right-hand side in FIG. 13 described above, a horizontal axis, a vertical axis on the left-hand side, and a vertical axis on the right-hand side in FIG. 14 represent an elapsed time (seconds), a flow rate (ml/minute) of the chemical liquid, and a flow rate (L/minute) of the heat fluid, respectively.

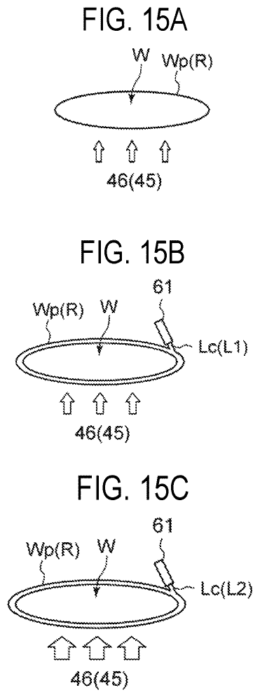

FIGS. 15A to 15C are diagrams for explaining a concept of a processing sequence of the third adjusted etching mode.

In the third adjusted etching mode, non-uniformity of the etching interface is suppressed by adjusting the temperature of the substrate W (especially the etching region R of the peripheral portion Wp) to control a progress of the etching process.

That is, the controller 93 (see FIG. 1) controls the heat fluid supplier 45 (the heating mechanism 44; see FIG. 2) in addition to the substrate rotator 11 and the processing liquid supplier 12 to perform each process as described below while rotating the substrate W supported by the holder 31.

In a preheating process, without supplying the chemical liquid Lc from the second processing liquid nozzle 61 to the substrate W, an inert gas (heat fluid) is ejected from the heat fluid ejector 46 of the heat fluid supplier 45 to a back surface of the substrate W at a relatively low flow rate (see FIG. 15A).

Thereafter, in a state in which the inert gas is being ejected from the heat fluid ejector 46 to the back surface of the substrate Wheat fluid, the chemical liquid Lc is supplied from the second processing liquid nozzle 61 to the peripheral portion Wp of the substrate W. Thus, an etching process and a heating process are performed simultaneously.

In particular, after the substrate W is supported by the substrate rotator 11 and before a liquid film of the chemical liquid Lc (especially a liquid film having a stable shape) is formed in the etching region R, the substrate W is heated with a first amount of heat by the heat fluid supplier 45 (see FIG. 15B). After the liquid film of the chemical liquid Lc (especially the liquid film having a stable shape) is formed in the etching region R, the substrate W is heated with a second amount of heat, which is greater than the first amount of heat, by the heat fluid supplier 45 while the chemical liquid Lc is supplied to the etching region R (see FIG. 15C). More specifically, the controller 93 controls the heat fluid supplier 45 such that a flow rate of the inert gas discharged from the heat fluid supplier 45 during a period in which the substrate W is heated with the second amount of heat is greater than that during a period in which the substrate W is heated with the first amount of heat (see FIGS. 15B and 15C).

Therefore, after the start of the supply of the chemical liquid Lc to the substrate W and before the shape of the liquid film of the chemical liquid Lc formed in the etching region R (especially the contour of the interface B on the side of the center of the substrate) becomes stable, etching the surface film Ws proceeds in a state in which the etching rate is relatively low. After the shape of the liquid film of the chemical liquid Lc formed in the etching region R becomes stable, etching the surface film Ws proceeds in a state in which the etching rate is relatively high.

Thus, until the shape of the liquid film of the chemical liquid Lc formed in the etching region R becomes stable, the surface film Ws is etched without exposing the substrate body Wb, which effectively suppresses stabilization of the liquid film from being inhibited by partial exposure of the substrate body Wb. After the shape of the liquid film of the chemical liquid Lc formed in the etching region R is stabilized, the surface film Ws can be efficiently etched.

In the adjusted etching mode performed as described above, the chemical liquid Lc supplied to the substrate W until the shape of the liquid film of the chemical liquid Lc formed in the etching region R is stabilized functions as the above-described processing liquid for liquid film formation. On the other hand, the chemical liquid Lc supplied to the substrate W after the shape of the liquid film of the chemical liquid Lc formed in the etching region R is stabilized functions as the above-described processing liquid for etching.

The preheating process and/or the heating process using the inert gas (heat fluid) may be combined with other adjusted etching modes (see the first and second adjusted etching modes described above) that adjust timings of starting and stopping the supply of the chemical liquid Lc and the DIWLd to the substrate W. Examples of the adjusted etching modes regarding such combinations will be described below.

### [Fourth Adjusted Etching Mode]

Next, a fourth adjusted etching mode, which is effective in promoting uniformity in the shaped of the etching interface, will be described.

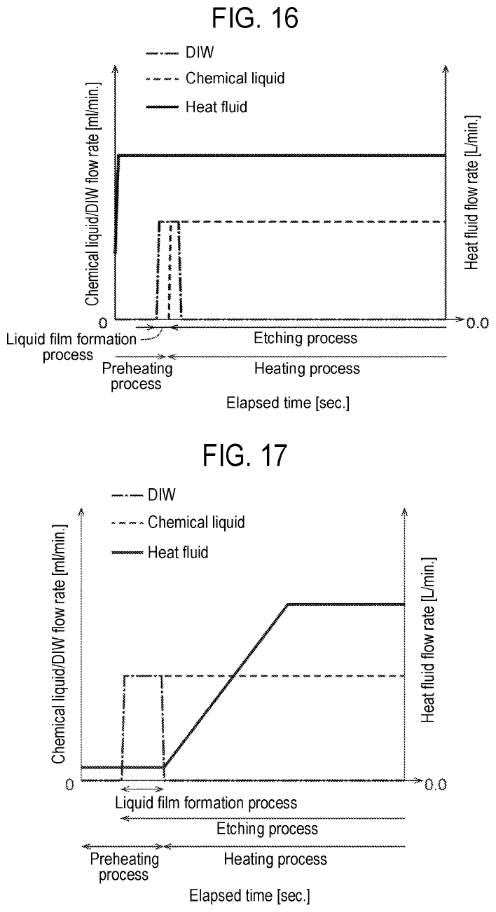

FIG. 16 is a graph illustrating an example of a processing sequence of the fourth adjusted etching mode. A horizontal axis in FIG. 16 represents an elapsed time (seconds), a vertical axis on the left-hand side represents a flow rate (ml/minute) of the chemical liquid Lc and DIWLd, and a vertical axis on the right-hand side represents a flow rate (L/minute) of the heat fluid.

This adjusted etching mode is based on a combination of the first adjusted etching mode (see FIG. 10) in which the etching process is started after the liquid film formation process and the adjusted etching mode (see FIG. 14) which includes heating the substrate W by an inert gas (heat fluid).

That is, in the adjusted etching mode illustrated in FIG. 16, an etching process using the chemical liquid Lc from the second processing liquid nozzle 61 is performed after a liquid film formation process using DIWLd from the first processing liquid nozzle 51, as in the first adjusted etching mode described above.

Further, prior to the liquid film formation process, an inert gas (heat fluid) is ejected from the heat fluid ejector 46 of the heat fluid supplier 45 to the back surface of the substrate W, and the temperature of the substrate W is increased. In the example illustrated in FIG. 16, an inert gas is ejected from the heat fluid ejector 46 to the substrate W at a substantially constant flow rate throughout almost the entire process. The process of increasing the temperature of the substrate W by the inert gas is classified as a preheating process before the etching process is started (e.g., during a progress of the liquid film formation process), and is classified as a heating process after the etching process is started.

In this adjusted etching mode, since the chemical liquid Lc contributing to etching the surface film Ws is not supplied to the substrate W before the etching process is started, it is basically unnecessary to suppress heating the substrate W for increasing an etching rate. Therefore, in this adjusted etching mode, unlike the third adjusted etching mode described above (see FIG. 14), the substrate W can be heated by the inert gas even before the etching process to the same extent as during the etching process, and a more efficient etching process can be achieved.

### [Fifth Adjusted Etching Mode]

Next, a fifth adjusted etching mode, which is effective in promoting uniformity in the shape of the etching interface, will be described.

FIG. 17 is a graph illustrating an example of a processing sequence of the fifth adjusted etching mode. Similar to FIG. 16 described above, a horizontal axis, a vertical axis on the left-hand side, and a vertical axis on the right-hand side in FIG. 17 represent an elapsed time (seconds), a flow rate (ml/minute) of the chemical liquid Lc and DIWLd, and a flow rate (L/minute) of the heat fluid, respectively.

This adjusted etching mode is based on a combination of the second adjusted etching mode (see FIG. 12) in which the etching process is started during the liquid film formation process and the adjusted etching mode (see FIG. 14) which includes heating the substrate W by the inert gas (heat fluid).

That is, in the fifth adjusted etching mode illustrated in FIG. 17, both the DIWLd from the first processing liquid nozzle 51 and the chemical liquid Lc from the second processing liquid nozzle 61 are supplied to the peripheral portion Wp of the substrate W to perform the liquid film formation process, as in the first adjusted etching mode described above. That is, both the DIWLd and the chemical liquid Lc are used as the processing liquid L1 for liquid film formation, and a liquid film of the DIWLd and the chemical liquid Lc (the processing liquid L1 for liquid film formation) is stably formed in the etching region R. In the example illustrated in FIG. 17, unlike the example illustrated in FIG. 12 described above, supplying the DIWLd and supplying the chemical liquid Lc to the peripheral portion Wp are started simultaneously in the liquid film formation process.

Thereafter, in this adjusted etching mode as well, the supply of the DIWLd to the etching region R is stopped and the liquid film formation process ends in a state in which the liquid film of the processing liquid L1 for liquid film formation is stably formed in the etching region R, as in the second adjusted etching mode. The supply of the chemical liquid Lc to the etching region R continues, and the etching process continues even after the liquid film formation process ends.

Further, prior to the liquid film formation process and the etching process, an inert gas (heat fluid) is ejected from the heat fluid ejector 46 of the heat fluid supplier 45 to the back surface of the substrate W, and the temperature of the substrate W is increased. However, in this adjusted etching mode, since the surface film Ws is etched even during the liquid film formation process, a flow rate of the inert gas is suppressed until the shape of the liquid film of the processing liquid L1 for liquid film formation in the etching region R becomes stable, as in the third adjusted etching mode described above (see FIG. 14).

That is, during a period before the shape of the liquid film of the processing liquid L1 for liquid film formation formed in the etching region R of the substrate W becomes stable (i.e., before the liquid film formation process ends), an inert gas is supplied from the heat fluid ejector 46 to the substrate W at a relatively low flow rate, which suppresses an etching rate from being increased. After the shape of the liquid film of the processing liquid L1 for liquid film formation formed in the etching region R becomes stable (i.e., after the liquid film formation process ends), the inert gas is supplied from the heat fluid ejector 46 to the substrate W at a relatively high flow rate, which promotes an increase in the etching rate.

Thus, until the shape of the liquid film of the processing liquid L1 for liquid film formation formed in the etching region R becomes stable, the surface film Ws is etched without exposing the substrate body Wb, which effectively suppresses stabilization of the liquid film from being inhibited by partial exposure of the substrate body Wb. After the shape of the liquid film of the chemical liquid Lc formed in the etching region R is stabilized, the surface film Ws can be efficiently etched.

### [Etching Mode Determination Method]

As described above, even when the etching interface becomes non-uniform in the standard etching modes (the first and second standard etching modes), the non-uniformity in the shape of the etching interface is effectively suppressed in the above-described adjusted etching modes (the first to fifth adjusted etching modes).

However, in reality, whether or not an etching interface can be made uniform in shape is determined by various etching conditions entangled with one another, and therefore cannot necessarily be determined in advance in a simple manner. For example, even for substrates W having the same characteristics in terms of specifications, etching interfaces of substrates from one lot may be made uniform by the standard etching modes, whereas etching interfaces of substrates from another lot may be made non-uniform by the standard etching modes.

Therefore, an etching mode for the substrate W to be processed may be adaptively determined by an etching mode determination method described below. For example, an appropriate etching mode may be determined by perform the etching mode determination method described below on a substrate W representing a plurality of substrates W to be processed, and the other substrates W may be processed according to the appropriate etching mode determined as described above.

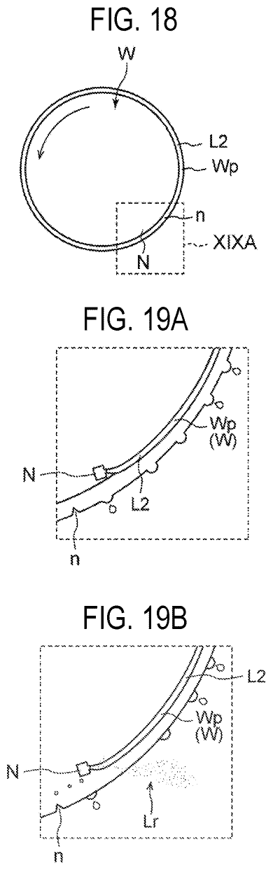

FIG. 18 is a plan view schematically illustrating an example of a substrate W to which the processing liquid L2 for etching (e.g., the chemical liquid Lc) is being supplied from the processing liquid nozzle N to the peripheral portion Wp. FIG. 19A is an enlarged plan view of a region indicated by reference symbol “XIXA” in FIG. 18, and especially illustrates an example in which the peripheral portion Wp of the substrate W to which the processing liquid L2 for etching is supplied has hydrophilic surface properties. FIG. 19B is an enlarged plan view of the region indicated by symbol “XIXA” in FIG. 18, and especially illustrates an example in which the peripheral portion Wp of the substrate W to which the processing liquid L2 for etching is supplied has hydrophobic surface properties.

In addition, a notch (cutout) of the substrate W illustrated in FIGS. 18 to 19B is indicated by reference symbol “n.” As is apparent from the position of the notch n in FIGS. 18 to 19B, FIG. 18 does not correspond in time to FIGS. 19A and 19B.

As illustrated in FIGS. 18 to 19B, the processing liquid L2 for etching discharged from the processing liquid nozzle N and supplied to the peripheral portion Wp of the substrate W exhibits different behaviors according to surface properties (especially hydrophilicity/hydrophobicity) of the peripheral portion Wp. That is, when the peripheral portion Wp has hydrophilic surface properties (see FIG. 19A), the processing liquid L2 for etching tends to spread on the peripheral portion Wp and is hardly repelled by the peripheral portion Wp. In contrast, when the peripheral portion Wp has hydrophobic surface properties (see FIG. 19B), at least a portion of the processing liquid L2 for etching is repelled by the peripheral portion Wp and tends to scatter outward from the peripheral portion Wp as a mist-like repelled liquid (Lr).

As described above, the processing liquid L2 for etching supplied to the peripheral portion Wp of the substrate W exhibits different behaviors according to the surface properties (especially hydrophilicity/hydrophobicity) of the peripheral portion Wp. Therefore, it is possible to select an appropriate etching mode based on the behavior.

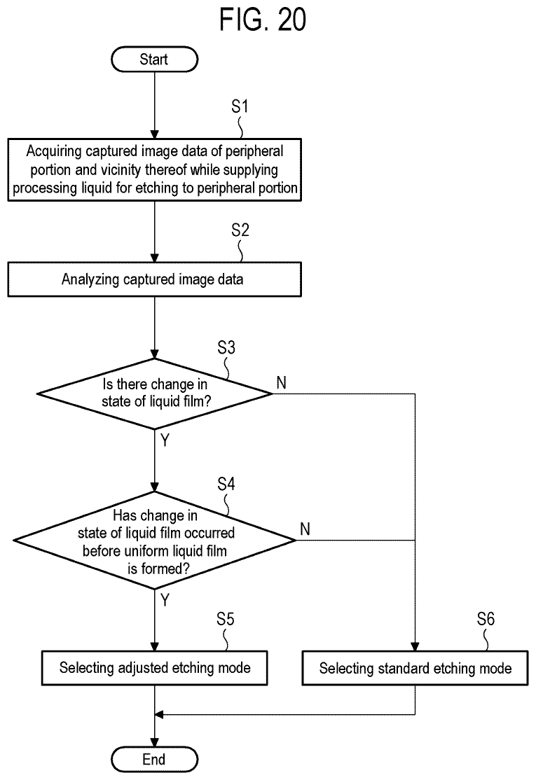

FIG. 20 is a flowchart illustrating an example of an etching mode determination method.

The etching mode determination method of FIG. 20 described below is executed appropriately controlling various devices constituting the substrate processing system 80 (the processing unit 10) by the controller 93 (see FIG. 1).

That is, under the control of the controller 93, as the substrate W is rotated by the substrate rotator 11, the processing liquid L2 for etching (e.g., the chemical liquid Lc) is supplied from the processing liquid supplier 12 to the etching region R in the peripheral portion Wp of the substrate W.

In addition, while the processing liquid L2 for etching is supplied to the etching region R (especially during a certain observation time range), the controller 93 acquires captured image data obtained by imaging the peripheral portion Wp and a vicinity of the peripheral portion Wp by using the imaging device 49 (see FIG. 2) (S1 of FIG. 20). The captured image data acquired as described above includes images (still images and/or moving images) showing a state and behavior of the processing liquid L2 for etching in the peripheral portion Wp and the vicinity of the peripheral portion Wp.

The above-described “observation time range” includes a “liquid film formation time,” which is a time period from a start of supplying the processing liquid L2 for etching by the processing liquid supplier 12 to the etching region R until a liquid film of the processing liquid L2 for etching having a stable shape is formed in the etching region R.

Thereafter, the controller 93 analyzes the captured image data (S2) and, based on the captured image data, detects presence or absence of change in a surface state of the peripheral portion Wp (especially the etching region R) of the substrate W during the observation time range. Generally, presence or absence of change in the surface state of the peripheral portion Wp is reflected in presence or absence of change in a state of the liquid film in the peripheral portion Wp. Therefore, the controller 93 determines, based on the captured image data, whether or not there is a change in the state of the liquid film of the processing liquid L2 for etching in the peripheral portion Wp during the observation time range (S3). For example, when the repelled liquid Lr (see FIG. 19B) changes from an observed state to an unobserved state, or when the repelled liquid Lr changes from an unobserved state to an observed state, it may be considered that there is a change in the state of the liquid film (and further, the surface state of the peripheral portion Wp).

The controller 93 determines whether or not to execute an adjusted etching mode based on the result of detecting presence or absence of change in the surface state of the substrate W. That is, when it is determined that there is no change in the state of the liquid film of the processing liquid L2 for etching in the peripheral portion Wp (further, the surface state of the peripheral portion Wp) (N in S3), the controller 93 selects a standard etching mode and does not execute an adjusted etching mode (S6).

In contrast, when it is determined that there is a change in the state of the liquid film of the processing liquid L2 for etching in the peripheral portion Wp (further, the surface state of the peripheral portion Wp) (Y in S3), the controller 93 determines whether the change in the state of the liquid film has occurred before or after a uniform liquid film having a stable shape is formed (S4). When the change in the state of the liquid film has occurred after, rather than before, the liquid film achieves a stable shape (N of S4), the controller 93 selects a standard etching mode and does not execute an adjusted etching mode (S6). On the other hand, when the change in the state of the liquid film has occurred before the liquid film has a stable shape (Y of S4), the controller 93 selects an adjusted etching mode rather than a standard etching mode and executes the adjusted etching mode (S5).

Whether or not the liquid film of the processing liquid L2 for etching in the peripheral portion Wp is a uniform liquid film having a stable shape can be determined, for example, by analyzing the captured image data by the controller 93 to obtain the state of the liquid film of the processing liquid L2 for etching in the peripheral portion Wp. A specific method for determining whether or not the liquid film is a uniform liquid film is not limited. For example, when the shape of the contour of the liquid film in the peripheral portion Wp (e.g., the contour of the interface B on the side of the center of the substrate) does not change for a predetermined period of time, or when a state in which the rate of change of the shape remains equal to or below a threshold for a predetermined period of time or longer, it may be considered that the liquid film is a uniform liquid film having a stable shape.

As described above, when detecting a change in the surface state of the peripheral portion Wp of the substrate W, the controller 93 can obtain a liquid film formation timing, which is a timing at which the shape of the liquid film of the processing liquid L2 for etching in the etching region R becomes stable, by analyzing the captured image data. Further, the controller 93 determines whether or not to execute an adjusted etching mode based on a timing at which the change in the surface state of the peripheral portion Wp of the substrate W has occurred and the liquid film formation timing. That is, when the timing at which the change in the surface state of the peripheral portion Wp has occurred is before the liquid film formation timing, an adjusted etching mode, rather than a standard etching mode, is executed. In contrast, when the timing at which the change in the surface state of the peripheral portion Wp has occurred is after the liquid film formation timing, a standard etching mode, rather than an adjusted etching mode, is executed.

When an adjusted etching mode is selected and executed as a result of the processing flow of FIG. 20, the controller 93 may select an optimal adjusted etching mode from a plurality of adjusted etching modes (see the first to fifth adjusted etching modes described above). Selecting the optimal adjusted etching mode can be performed based on various processing conditions, and may be performed based on, for example, the liquid film formation time. As described above, the “liquid film formation time” is a time period from the start of supplying the processing liquid L2 for etching by the processing liquid supplier 12 to the etching region R until the liquid film of the processing liquid L2 having the stable shape is formed in the etching region R, and can be acquired by analyzing the captured image data by the controller 93.

For example, when the liquid film formation time is relatively short (e.g., when “liquid film formation time ≤one second”), an adjusted etching mode (e.g., the first or fourth adjusted etching mode described above) in which the etching process is performed after the liquid film formation process may be selected. On the other hand, when the liquid film formation time is relatively long (e.g., when “liquid film formation time>one second”), an adjusted etching mode (e.g., the second, third, or fifth adjusted etching mode described above) in which the etching process is started while the liquid film formation process is in progress may be selected.

It should be noted that the embodiments and modifications disclosed herein are exemplary in all aspects and are not restrictive. The above-described embodiments and modifications may be omitted, replaced, or modified in various forms without departing from the scope and spirit of the appended claims. For example, the above-described embodiments and modifications may be combined in whole or in part, and embodiments other than those described above may be combined with the above-described embodiments or modifications. In addition, the effects of the present disclosure described herein are merely examples, and other effects may also be obtained.

A technical category for embodying the above-described technical concept is not particularly limited. For example, the above-described technical concept may be embodied by a computer program for executing one or multiple sequences (steps) included in a method of manufacturing or using the above-described apparatus on a computer. Further, the above-described technical concept may be embodied by a non-transitory computer-readable recording medium in which such a computer program is recorded.

1. A substrate processing apparatus, comprising:
a substrate rotator configured to hold and rotate a substrate;
a processing liquid supplier configured to supply a processing liquid to a peripheral portion of the substrate; and
a controller configured to control the substrate rotator and the processing liquid supplier,
wherein the controller controls the substrate rotator and the processing liquid supplier in an adjusted etching mode, in which a liquid film is formed in an etching region of the peripheral portion by supplying a processing liquid for liquid film formation from the processing liquid supplier to the peripheral portion while rotating the substrate, and subsequently, in a state in which the liquid film is formed, a surface film of the etching region is etched by supplying a processing liquid for etching to the etching region.

2. The substrate processing apparatus of claim 1, wherein the processing liquid for liquid film formation is an etching liquid having a lower concentration of an etching component for etching the surface film than the processing liquid for etching.

3. The substrate processing apparatus of claim 2, wherein the processing liquid for liquid film formation is a liquid mixture of a processing liquid that etches the surface film and a processing liquid that does not etch the surface film.

4. The substrate processing apparatus of claim 1, wherein the processing liquid for liquid film formation is a processing liquid that does not etch the surface film.

5. The substrate processing apparatus of claim 1,
wherein the processing liquid supplier comprises:
a first processing liquid supplier configured to supply a first processing liquid that does not etch the surface film to the peripheral portion; and
a second processing liquid supplier configured to supply a second processing liquid that etches the surface film to the peripheral portion;
wherein the controller further controls the substrate rotator and the processing liquid supplier to perform:
while rotating the substrate,
supplying the first processing liquid from the first processing liquid supplier to the etching region while supplying the second processing liquid from the second processing liquid supplier to the etching region is stopped;
subsequently, supplying the second processing liquid from the second processing liquid supplier to the etching region while continuously supplying the first processing liquid from the first processing liquid supplier to the etching region; and
subsequently, continuously supplying the second processing liquid from the second processing liquid supplier to the etching region while supplying the first processing liquid from the first processing liquid supplier to the etching region is stopped.

6. The substrate processing apparatus of claim 5, wherein the controller performs:
while rotating the substrate,
supplying the first processing liquid from the first processing liquid supplier to the etching region while supplying the second processing liquid from the second processing liquid supplier to the etching region is stopped;
subsequently, forming the liquid film by supplying the second processing liquid from the second processing liquid supplier to the etching region while continuously supplying the first processing liquid from the first processing liquid supplier to the etching region; and
subsequently, continuously supplying the second processing liquid from the second processing liquid supplier to the etching region while supplying the first processing liquid from the first processing liquid supplier to the etching region is stopped.

7. The substrate processing apparatus of claim 1, further comprising a heating mechanism controlled by the controller and configured to heat the substrate,
wherein the controller controls the heating mechanism to perform:
after the substrate is held by the substrate rotator, heating the substrate with a first amount of heat until the liquid film is formed in the etching region; and
subsequently, heating the substrate with a second amount of heat, which is greater than the first amount of heat, while supplying the processing liquid for etching to the etching region.

8. The substrate processing apparatus of claim 7, wherein the heating mechanism includes a heat fluid supplier configured to discharge a heat fluid heated by a heater, and heats the substrate by using the heat fluid discharged from the heat fluid supplier, and
wherein the controller controls the heat fluid supplier such that a flow rate of the heat fluid discharged from the heat fluid supplier while the substrate is heated with the second amount of heat is greater than a flow rate of the heat fluid discharged from the heat fluid supplier while the substrate is heated with the first amount of heat.

9. The substrate processing apparatus of claim 1, further comprising an imaging device configured to capture an image of the substrate held by the substrate rotator,
wherein the controller performs:
while rotating the substrate, supplying the processing liquid for etching from the processing liquid supplier to the etching region;
acquiring captured image data obtained by capturing an image of the peripheral portion by the imaging device while supplying the processing liquid for etching to the etching region;
detecting presence or absence of change in a surface state of the substrate based on the captured image data; and
determining whether or not to execute the adjusted etching mode based on a detection result of the presence or absence of change in the surface state of the substrate.

10. The substrate processing apparatus of claim 9, wherein the controller further performs:
when detecting a change in the surface state of the substrate, acquiring a liquid film formation timing, which is a timing at which the liquid film is formed in the etching region, by analyzing the captured image data; and
determining whether or not to execute the adjusted etching mode based on a timing at which the change in the surface state of the substrate has occurred and the liquid film formation timing.

11. A substrate processing method of processing a substrate in an adjusted etching mode, comprising:
forming a liquid film in an etching region of a peripheral portion of the substrate by supplying a processing liquid for liquid film formation to the peripheral portion while rotating the substrate; and
in a state in which the liquid film is formed, etching a surface film of the etching region by supplying a processing liquid for etching to the etching region.

12. The substrate processing method of claim 11, wherein the processing liquid for liquid film formation is an etching liquid having a lower concentration of an etching component than the processing liquid for etching.

13. The substrate processing method of claim 12, wherein the processing liquid for liquid film formation is a liquid mixture of a processing liquid that etches the surface film and a processing liquid that does not etch the surface film.

14. The substrate processing method of claim 11, wherein the processing liquid for liquid film formation is a processing liquid that does not etch the surface film.

15. The substrate processing method of claim 11, further comprising:
while rotating the substrate,
supplying a first processing liquid to the etching region while supplying a second processing liquid to the etching region is stopped;
subsequently, supplying the second processing liquid to the etching region while continuously supplying the first processing liquid to the etching region; and
subsequently, continuously supplying the second processing liquid to the etching region while supplying the first processing liquid to the etching region is stopped.

16. The substrate processing method of claim 15, further comprising:
while rotating the substrate,
supplying the first processing liquid to the etching region while supplying the second processing liquid to the etching region is stopped;
subsequently, forming the liquid film by supplying the second processing liquid to the etching region while continuously supplying the first processing liquid to the etching region; and
subsequently, continuously supplying the second processing liquid to the etching region while supplying the first processing liquid to the etching region is stopped.

17. The substrate processing method of claim 11, further comprising:
heating the substrate with a first amount of heat until the liquid film is formed in the etching region; and
heating the substrate with a second amount of heat, which is greater than the first amount of heat, while supplying the processing liquid for etching to the etching region.

18. The substrate processing method of claim 17,
wherein the substrate is heated by using a heat fluid discharged from a heat fluid supplier, and
wherein a flow rate of the heat fluid discharged from the heat fluid supplier while the substrate is heated with the second amount of heat is greater than a flow rate of the heat fluid discharged from the heat fluid supplier while the substrate is heated with the first amount of heat.

19. The substrate processing method of claim 11, further comprising:
while rotating the substrate, supplying the processing liquid for etching to the etching region;
acquiring captured image data of the peripheral portion by an imaging device while supplying the processing liquid for etching to the etching region;
detecting presence or absence of change in a surface state of the substrate based on the captured image data; and
determining whether or not to execute the adjusted etching mode based on a detection result of the presence or absence of change in the surface state of the substrate.

20. The substrate processing method of claim 19, further comprising:
when a change in the surface state of the substrate is detected, acquiring a liquid film formation timing, which is a timing at which the liquid film is formed in the etching region, by analyzing the captured image data; and
determining whether or not to execute the adjusted etching mode based on a timing at which the change in the surface state of the substrate has occurred and the liquid film formation timing.
